(19) United States
(12) Patent Application Publication
(10) Pub. No.: US 2020/0037477 A1
(43) Pub. Date: Jan. 30, 2020

(54) Printed Wire Board Stand-offs

(71) Applicant: Frontier Electronic Systems Corp., Stillwater, OK (US)

(72) Inventors: Kurt Ashley McLain, Stillwater, OK (US); Scott Andrew Briggs, Stillwater, OK (US)

(73) Assignee: Frontier Electronic Systems Corp., Stillwater, OK (US)

(21) Appl. No.: 16/409,255

(22) Filed: May 10, 2019

Related U.S. Application Data
(60) Provisional application No. 62/677,600, filed on May 29, 2018.

(51) Int. Cl. H05K 13/00

(52) U.S. Cl. CPC H05K 13/0069

(57) ABSTRACT

The embodiments of the printed wire board stand-off are comprised of a Printed Wire Board (“PWB”) stand-off; a PWB stand-off rail fixture; a PWB a stand-off holder; or a PWB male stand-off, or any combination thereof. The PWB stand-off is comprised of a large stand-off cylinder and an elongated stand-off cylinder. The PWB a stand-off rail fixture is comprised of two sides, a top, a set screw aperture, and a set screw. The PWB stand-off carrier is comprised of a base, a vertical post, and a handle. The PWB male stand-off is comprised of a male stand-off base, a male stand-off post, and a male thread.

### CROSS-REFERENCE TO RELATED APPLICATIONS

Not applicable

### STATEMENT REGARDING FEDERALLY SPONSORED RESEARCH OR DEVELOPMENT

Not applicable

### FIELD OF THE EMBODIMENTS

The field of the embodiments is accessories for the manufacturing and inspection of printed wire boards. More specifically, the embodiments are directed to stand-offs used to hold and protect printed wire boards during manufacture and inspection.

### BACKGROUND OF THE EMBODIMENTS

Once custom printed wire boards (PWB) are constructed, several manipulations of the PWBs are required including populating the PWB with electronic components, application of input-output terminals and connectors, and implementing various inspection steps and procedures. During the course of these procedures the board must be handled to manipulate the PWB for the various procedures. During these procedures the PWB and the components installed onto the PWB must be protected from damage. The typical manner that PWBs are handled are with ¼ inch round or hexagonal standoffs. These ¼ inch standoffs do not serve to protect the PWB and are difficult to handle. The purpose of the embodiments described herein are designed to overcome these and other limitations of these ¼ inch standoffs.

### SUMMARY OF THE EMBODIMENTS

The embodiments of the Printed Wire Board Stand-Offs are comprised of a Printed Wire Board (“PWB”) stand-off; a PWB stand-off rail fixture; a PWB a stand-off holder; or a PWB male stand-off, or any combination thereof. The PWB stand-off is comprised of a large stand-off cylinder and an elongated stand-off cylinder. The PWB stand-off rail fixture is comprised of two sides, a top, a set screw aperture, and a set screw. The PWB stand-off carrier is comprised of a base, a vertical post, and a handle. The PWB male stand-off is comprised of a male stand-off base, a male stand-off post, and a male thread.

There has thus been outlined, rather broadly, the more important features of the embodiments of the Printed Wire Board Stand-Off in order that the detailed description thereof that follows may be better understood, and in order that the present contribution to the art may be better appreciated. There are, of course, additional features of the embodiments that will be described hereinafter and which will form the subject matter of the claims appended hereto.

In this respect, before explaining at least one embodiment of the embodiments in detail, it is to be understood that the embodiment is not limited in this application to the details of construction and to the arrangements of the components set forth in the following description or illustrated in the drawings. The embodiment or embodiments are capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be used as a basis for the designing of other structures, methods and systems for carrying out the several purposes of the embodiments. Additional benefits and advantages of the embodiments will become apparent in those skilled in the art to which the present embodiments relate from the subsequent description of the preferred embodiment and the appended claims, taken in conjunction with the accompanying drawings. It is important, therefore, that the claims be regarded as including such equivalent constructions insofar as they do not depart from the spirit and scope of the embodiments.

Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application. The abstract is neither intended to define the embodiments of the application which is measured by the claims, nor is it intended to be limiting as to the scope of the embodiments in any way.

### BRIEF DESCRIPTION OF THE DRAWINGS

FIG. 1A is a top view of an embodiment of Printed Wire Board Stand-Off; FIG. 1B is a side view of an embodiment of Printed Wire Board Stand-Off; FIG. 1C is a bottom view of an embodiment of Printed Wire Board Stand-Off; FIG. 1D is a perspective view of an embodiment of Printed Wire Board Stand-Off.

FIG. 2A is a side view of an embodiment of Printed Wire Board Stand-Off showing a stand-off and a stand-off holder; FIG. 2B is a top view of an embodiment of Printed Wire Board Stand-Off showing a stand-off and a stand-off holder; FIG. 2C is a perspective view of an embodiment of Printed Wire Board Stand-Off showing a stand-off and a stand-off holder; FIG. 2D is a side view of an embodiment of Printed Wire Board Stand-Off showing a stand-off and a stand-off holder; FIG. 2E is a front view of an embodiment of Printed Wire Board Stand-Off showing a stand-off and a stand-off holder; FIG. 2F is a side view of an embodiment of Printed Wire Board Stand-Off showing a stand-off and a stand-off holder.

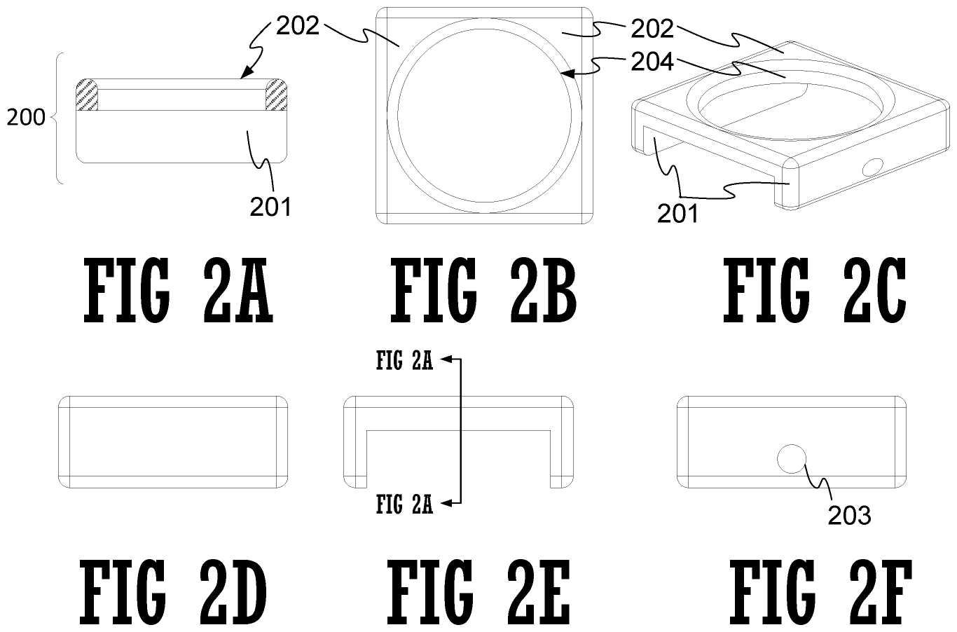

FIG. 3A is a top view of an embodiment of Printed Wire Board Stand-Off showing a stand-off carrier; FIG. 3B is a front view of an embodiment of Printed Wire Board Stand-Off showing a stand-off carrier; FIG. 3C is a bottom view of an embodiment of Printed Wire Board Stand-Off showing a stand-off carrier; FIG. 3D is a side view of an embodiment of Printed Wire Board Stand-Off showing a stand-off carrier; FIG. 3E is a perspective view of an embodiment of Printed Wire Board Stand-Off showing a stand-off carrier.

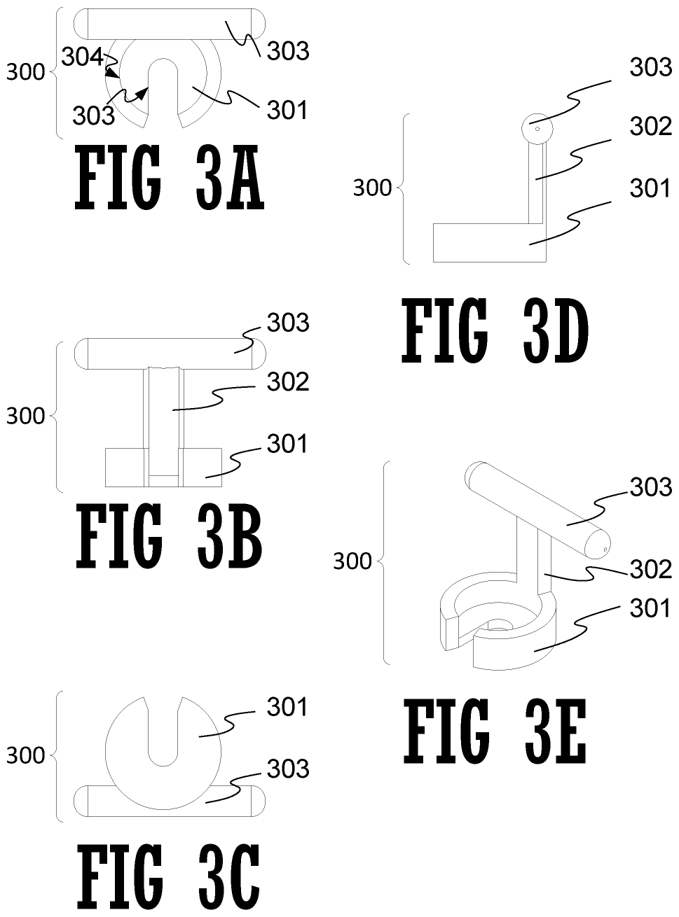

FIG. 4A is a sectional view of an embodiment of Printed Wire Board Stand-Off showing a stand-off rail fixture; FIG. 4B is a top view of an embodiment of Printed Wire Board Stand-Off showing a stand-off rail fixture; FIG. 4C is a perspective view of an embodiment of Printed Wire Board Stand-Off showing a stand-off rail fixture.

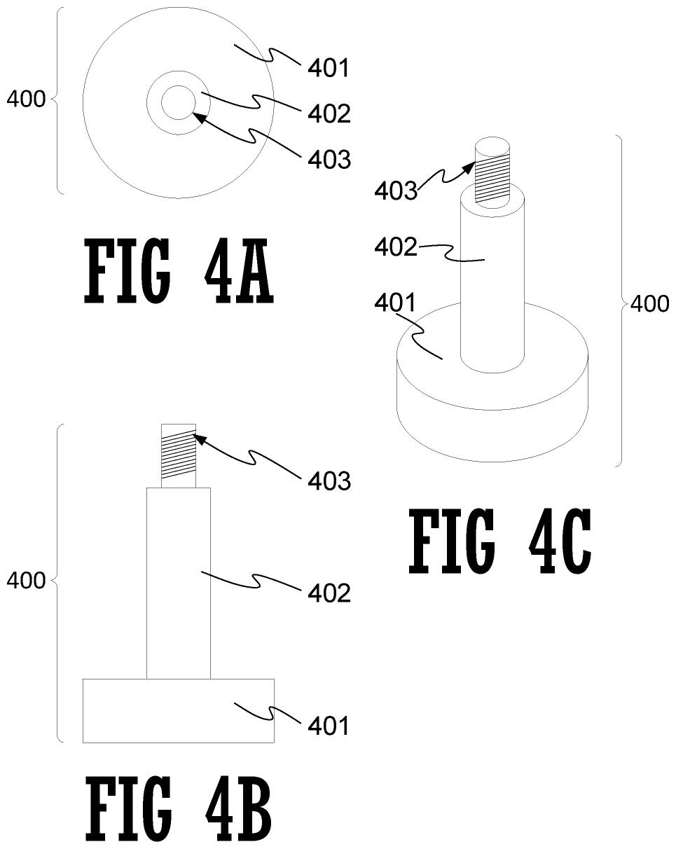

FIG. 5A is a perspective view of an embodiment of Printed Wire Board Stand-Off showing an embodiment of a male stand-off; FIG. 5B is a side view of an embodiment of Printed Wire Board Stand-Off showing an embodiment of a male stand-off; FIG. 5C is a perspective view of an embodiment of Printed Wire Board Stand-Off showing an embodiment of a male stand-off; FIG. 5D is a perspective view of an embodiment of Printed Wire Board Stand-Off showing an embodiment of a male stand-off; FIG. 5E is a perspective view of an embodiment of Printed Wire Board Stand-Off showing an embodiment of a male stand-off.

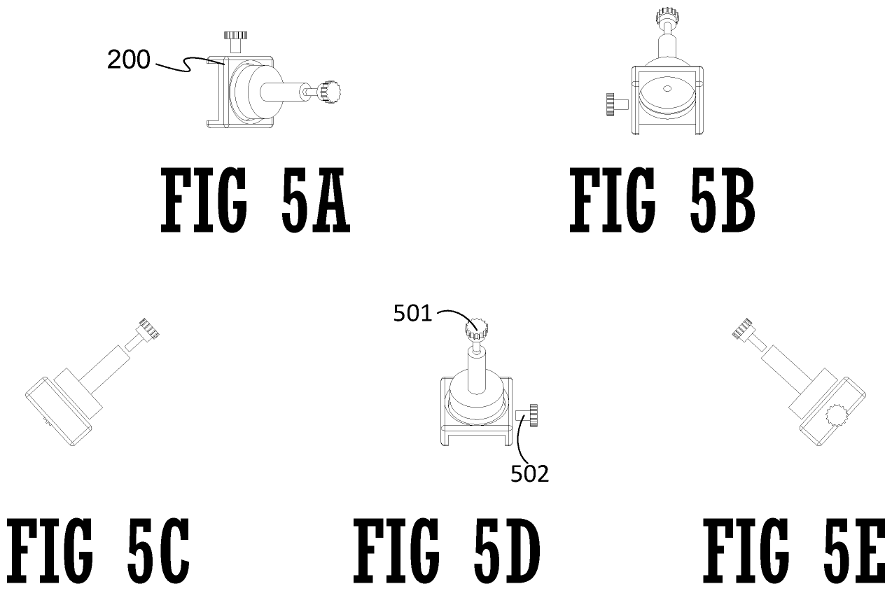

### DETAILED DESCRIPTION OF THE PREFERRED EMBODIMENTS

Embodiments of the Printed Wire Board Stand-Off are comprised of a Printed Wire Board (“PWB”) stand-off 100; a PWB stand-off rail fixture 200; a PWB a stand-off holder 300; or a PWB male stand-off, or any combination thereof.

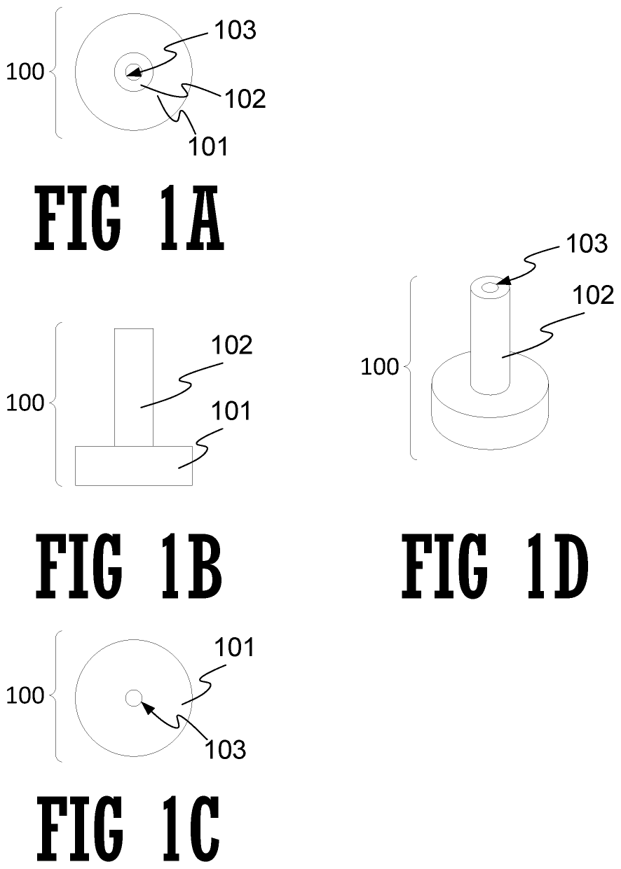

The PWB stand-off 100 is comprised of a large stand-off cylinder 101 and an elongated stand-off cylinder 102. The large stand-off cylinder 101 and the elongated stand-off cylinder 102 are integrally manufactured to form a PWB stand-off. See FIGS. 1A, 1B, 1C, and 1D. The elongated stand-off cylinder 102 forms internal female threads 103 so that the PWB stand-off 100 can be threadedly connected to another PWB stand-off 100 or to another PWB appliance.

The PWB stand-off rail fixture 200 is comprised of two sides 201, a top 202, a set screw aperture 203, and a set screw 502. The two sides 201 form a base which is designed to be placed over a standard electronics rail. The two sides 201 that form the base can be secured to the rail via the set screw 502. The two sides 201 support a top 202. The top 202 forms an aperture 204 that accepts a PWB stand-off 100. The PWB stand-off 100 rests securely within the aperture 204 and thereby supports the PWB stand-off 100 and in turn the printed wire board. The standoffs are not secured to the rail fixture so that the operators can easily move or flip the assemblies.

The PWB stand-off carrier 300 is comprised of a base 301, a vertical post 302, and a handle 303. The base 301 is a circular base with an opening 303 formed in the middle of the base that can accept an elongated stand-off cylinder 102. The base 301 is comprised of a large aperture 304 that serves to accept large stand-off cylinder 101. When the base 301 is placed over the elongated stand-off cylinder 102 and accepts the large stand-off cylinder 101, the PWB stand-off carrier 300 can be used to carry and support a PWB.

The PWB male stand-off 400 is comprised of a male stand-off base 401, a male stand-off post 402, and a male thread 403. The male stand-off base 401, a male stand-off post 402, and a male thread 403 are all integrally formed and manufactured into a single unit. The male thread 403 of PWB male stand-off 400 can be used to engage with the internal female threads 103 of a PWB a stand-off 100 to build a stand-off to meet the needs of the user.

Any combination of the Printed Wire Board (“PWB”) stand-off 100; the PWB stand-off rail fixture 200; the PWB stand-off holder 300; and the PWB male stand-off can be used in conjunction with a PWB to support and manipulate that PWB.

In an embodiment of the PWB Stand-Off 100, the large stand-off cylinder 101 is approximately ¼ in long and ¾ in in diameter. Further the elongated stand-off cylinder 102 is approximately ¾ in long and ¼ in in diameter.

What is claimed is:

1. A printed wire board stand-off comprised of a Printed Wire Board stand-off; a PWB stand-off rail fixture; a PWB a stand-off holder; a PWB male stand-off; or any combination of the PWB stand-off rail fixture; PWB a stand-off holder; and the PWB male stand-off.
